(19) United States
(12) Patent Application Publication
(10) Pub. No.: US 2011/0181452 A1
(43) Pub. Date: Jul. 28, 2011

(54) Usage of Speaker Microphone for Sound Enhancement

(75) Inventors: Mark RAIFEL, Raanana (IL); Yaakov Chen, Rishon Le-tzion (IL)

(73) Assignee: DSP Group, Ltd., Herzelia (IL)

(21) Appl. No.: 12/695,171

(22) Filed: Jan. 28, 2010

(51) Int. Cl. H03M 1/00

(52) U.S. Cl. 341/110

(57) ABSTRACT

The method and system use a speaker available in an audio end device when not in use as a microphone. The speaker is utilized for enhancing the sound quality received by the person or device at the near end, i.e., the user of the device, or the speaker at the far end, i.e., the speaker with whom the near-end speaker is communicating. Exemplary applications are shown for such utilization, including single or dual microphone near-end automatic listening enhancement, acoustic echo cancellation or suppression with or without double talk detection, and microphone array noise reduction.

### TECHNICAL FIELD

The present invention relates to audio systems in general, and to a system and method for sound enhancement in audio systems by using a speaker as a microphone.

### BACKGROUND

A loudspeaker is a transducer that turns an electrical signal into sound waves. A microphone performs the opposite transduction, receiving a sound wave and emitting an electric signal. A speaker and a microphone contain the same basic elements, being a diaphragm, a coil and a magnet. Therefore, speakers can actually work “in reverse”, and function also as microphones.

However, the result of a speaker used as a microphone is a poor-quality microphone having low sensitivity and limited frequency response, particularly in the high end frequencies. Therefore, speakers are used as microphones in applications in which high quality or sensitivity is not required, such as intercoms or walkie-talkies, which usually operate in half-duplex, i.e. only one side of the conversation can speak at a time. Yet another known usage for a speaker as a microphone relates to placing a medium-size woofer closely in front of a bass drum in a drum set, to transduce low frequency sound. Since a relatively massive membrane is unable to transduce high frequencies, placing a speaker in front of a kick drum may be helpful in reducing cymbal and snare leakage into the kick drum sound.

Therefore, speakers are currently used as microphones only in environments in which high sensitivity or high quality is not required, or wherein the low sensitivity of the microphone is an advantage.

On the other hand, there are environments, such as full duplex environments, which can benefit from an additional microphone, but the cost of adding a microphone, or the limited physical space, disable such addition.

There is therefore a need in the art for a method, system and applications utilizing speakers turned into microphones, for enhancing the sound within an audio system.

### SUMMARY

A method and system for using speaker as a microphone for enhancing sound within an audio system.

A first aspect of the disclosure relates to a system for enhancing audio quality in a communication device in which a near-end user is communicating with a far-end, comprising: a speaker connected as a microphone; an analog processor for processing a first analog signal output by the speaker and outputting an enhanced analog signal; an analog to digital converter for converting the enhanced analog signal into a digital speaker signal; and a sound enhancement processor for receiving the digital speaker signal and a second signal produced from near-end audio or from far-end audio, and for generating an enhanced digital signal. Within the system, the sound enhancement processor is optionally an acoustic echo cancellation or acoustic echo suppression processor, the first analog signal may also comprise a signal produced from the far end audio, the second signal may be produced from far end audio, and the enhanced digital signal is optionally transmitted to the far end. Within the system, the sound enhancement processor is optionally a double talk or signal activity detection processor, and the system optionally further comprises: a microphone transmitting a second analog signal; a second analog processor for processing the second analog signal and obtaining an enhanced second analog signal; a second analog to digital converter for converting the enhanced second analog signal into a microphone digital signal; and an acoustic echo cancellation or acoustic echo suppression processor for receiving the microphone digital signal, the enhanced digital signal output by the double talk or signal activity detection processor, and the second signal produced from far end audio, and for producing output signal, wherein the first analog signal may also comprise a signal produced from the far end audio, and wherein the output signal may be transmitted to the far-end. Within the system, the sound enhancement processor is a optionally a microphone array noise reduction processor, the system optionally further comprising: one or more microphones transmitting one or more second analog signals; one or more second analog processors for processing the second analog signals and obtaining one or more second enhanced analog signals; and one or more second analog to digital, converters for converting the second enhanced analog signals into one or more microphone digital signals; wherein the second signal is optionally the microphone digital signal produced from the near end audio, and wherein the enhanced digital signal is transmitted to the far end. Within the system, the sound enhancement processor is optionally an automatic listening enhancement processor, the system further comprising: a level adjustment processor for adjusting the far end audio in accordance with a signal output by the automatic listening enhancement processor and for outputting an adjusted digital signal; a digital to analog convertor for converting the adjusted digital signal into an adjusted analog signal; and a second analog processor for processing the adjusted analog signal and outputting an enhanced analog signal, wherein the second signal is optionally the adjusted digital signal, and wherein the first analog signal may also comprise a signal produced from the far end audio, and wherein the enhanced analog signal is optionally transmitted to the near end. Within the system, the sound enhancement processor is optionally an automatic listening enhancement processor, the system optionally further comprising: a microphone transmitting a microphone analog signal; a second analog processor for processing the microphone analog signal, and outputting an enhanced microphone signal; a second analog to digital converter for converting the enhanced microphone signal into a microphone digital signal; and a level adjustment processor for adjusting the far end audio in accordance with a signal output by the ac automatic listening enhancement processor and for outputting an adjusted digital signal, wherein the second signal is the adjusted digital signal and the microphone digital signal, and wherein the enhanced digital signal is transmitted to the near end.

Another aspect of the disclosure relates to a method for enhancing audio quality in a communication device in which a near-end user is communicating with a far-end, comprising: receiving a first analog signal from a speaker connected as a microphone; processing the analog signal; converting the analog signal to a digital signal; performing sound processing on the digital signal with a second signal produced from near-end audio or from far-end audio, to obtain an enhanced signal; and transmitting the enhanced signal or a product thereof for enhancing audio transmitted to the near-end or to the far-end. Within the method, the sound processing is optionally acoustic echo cancellation or acoustic echo suppression, and the first analog signal optionally comprises a signal produced from the far end audio, and the second signal is optionally produced from the far-end audio, and wherein the enhanced digital signal is optionally transmitted to the far end. The method can further comprise: receiving a second analog signal from a microphone; processing the second analog signal to obtain a second enhanced analog signal; converting the second enhanced analog signal into a microphone digital signal; and performing acoustic echo cancellation or acoustic echo suppression on the microphone digital signal, wherein the sound processing is optionally double talk detection or signal activity detection, and wherein the acoustic echo cancellation or acoustic echo suppression is performed in accordance with the double talk detection or signal activity detection, and in accordance with the second signal produced from far-end audio, and wherein the first analog signal also comprises a signal produced from the far end audio, and wherein the enhanced digital signal is optionally transmitted to the far end. The method can further comprise: receiving one or more second analog signals from one or more microphones; processing the second analog signals to obtain one or more second enhanced analog signals; converting the second enhanced analog signals into microphone digital signals, wherein the sound processing is microphone array noise reduction, and wherein the enhanced digital signal is transmitted to the far end. Within the method, the sound processing is optionally automatic listening enhancement producing an automatic listening enhancement signal, the method further comprising: adjusting the level of the far end signal in accordance with the automatic listening enhancement signal to obtain an adjusted digital signal; converting the adjusted digital signal into an adjusted analog signal; processing the adjusted analog signal, wherein the first analog signal optionally comprises a signal produced from the far end audio after adjustment, and wherein the enhanced digital signal is optionally transmitted to the near end. Within the method, the sound processing is optionally automatic listening enhancement producing an automatic listening enhancement signal, the method further optionally comprising: adjusting the level of the far end signal in accordance with the automatic listening enhancement analysis signal to obtain an adjusted digital signal; converting the adjusted digital signal into an adjusted analog signal; processing the adjusted analog signal; transferring the adjusted analog signal to the speaker; receiving a second analog signal from a microphone; processing the second analog signal to obtain a second enhanced analog signal; and converting the second enhanced analog signal into a microphone digital signal, wherein the second signal is the adjusted digital signal and the microphone digital signal, and wherein the enhanced digital signal is transmitted to the near end.

### BRIEF DESCRIPTION OF THE DRAWINGS

The present invention will be understood and appreciated more fully from the following detailed description taken in conjunction with the drawings in which corresponding or like numerals or characters indicate corresponding or like components. Unless indicated otherwise, the drawings provide exemplary embodiments or aspects of the disclosure and do not limit the scope of the disclosure. In the drawings:

FIG. 1 is a schematic illustration of a mobile phone having two speakers, in which the system and method of the disclosure can be used;

FIG. 2A is a flowchart of the main steps in a method for enhancing sound by using a speaker as a microphone, in accordance with the disclosure;

FIG. 2B is a block diagram of the main system in a method for using a speaker as a microphone for sound enhancement, in accordance with the disclosure;

FIG. 3 is a schematic block diagram of a system using a speaker as a microphone for echo cancellation and suppression, in accordance with a first embodiment of the disclosure;

FIG. 4 is a schematic block diagram of a system using a speaker as a microphone for echo cancellation and suppression when another microphone is available, in accordance with a second embodiment of the disclosure;

FIG. 5 is a schematic block diagram of a system for microphone array noise reduction of the sound transmitted to the far-end, in accordance with a third embodiment of the disclosure;

FIG. 6 is a schematic circuit for enhancing sound by using a speaker as a microphone for automatic listening enhancement, in accordance with a fourth embodiment of the disclosure; and

FIG. 7 is a schematic circuit for enhancing sound by using a speaker as a microphone for automatic listening enhancement when another microphone is available, in accordance with a fifth embodiment of the disclosure.

### DETAILED DESCRIPTION

Multiple communication end devices comprise more than one speaker. For example, many mobile phones or wireless phones have an earpiece, as well as another speaker, such as a handset speaker, a base station speaker or a handsfree speaker which may be placed at the back side of the device. The disclosed method, apparatus and applications disclose use of any speaker available in a device, whether the device comprises a single speaker or multiple speakers. The disclosure relates to the usage of any speaker which is connected as a microphone, for audio enhancement purposes.

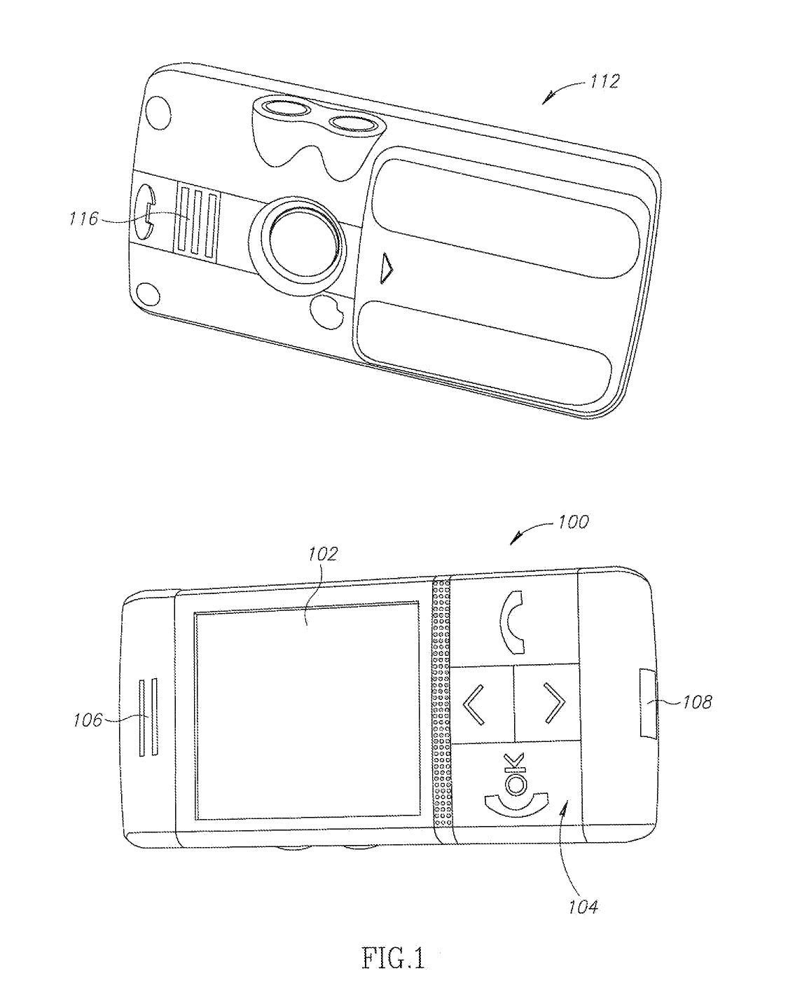

Referring now to FIG. 1, showing a schematic illustration of a mobile phone, in which the disclosed method and apparatus and some applications can be used.

The front side of the phone, referred as 100, comprises a display 102, some buttons or other controls 104, an earpiece 106 through which the speaker hears the far-end, i.e., the sound received from the party the user is communicating with, and a microphone 108 which receives the near-end sound, i.e. what the speaker says and other audio in the environment of the device.

The back side of the phone, referred to as 112, comprises additional components, and particularly a speaker 116. Speaker 116 is optionally used for ringing, playing music, and in handsfree conversation.

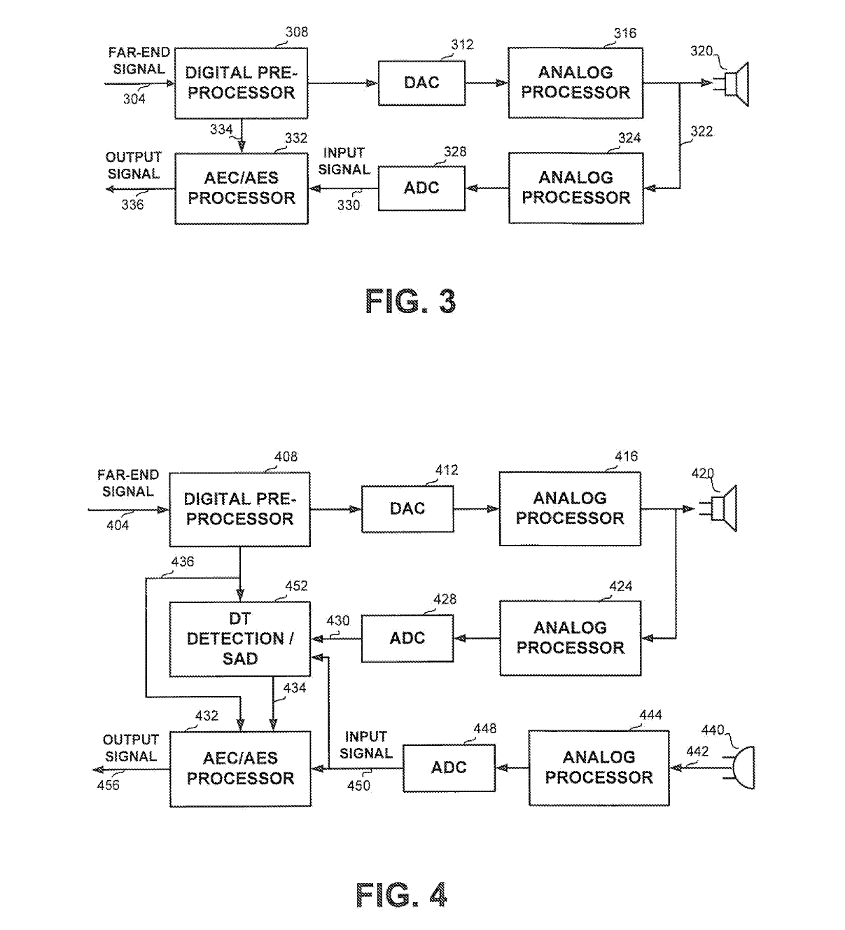

In conversations in which the speaker uses earpiece 106, speaker 116 is not used. Therefore speaker 116 or earpiece 106 can be connected as a microphone and receive audio from the environment. The audio can be used in various audio enhancement applications, as detailed in association with FIGS. 3-7 below.

It will be appreciated that usage of the disclosure is not limited to the mobile phone shown, or to any mobile phone in general. Rather the method and system can utilize any available speaker in a wired or wireless phone, or in any audio communication device.

The disclosure can relate to a speaker which is usually used for purposes such as outputting the sound in a hands-free conversation, in which more power is required since the device is not adjacent to the listener's ear, or when ringing, playing music or the like.

Specifically, in regular operation mode the back speaker is generally not used, and can therefore be utilized for enhancing the sound quality received by the speaker at the near end, i.e., the person using the device, or the speaker at the far end, i.e., the speaker with whom the near-end speaker is communicating. Utilization of the speaker for audio enhancement is performed by using the speaker as a microphone, i.e., connecting the speaker as a microphone within the circuit, and using the electrical signal output by the speaker.

It will be appreciated that the speaker-as microphone can still be used as a speaker, in addition to being used as a microphone, i.e. it can have dual functionality.

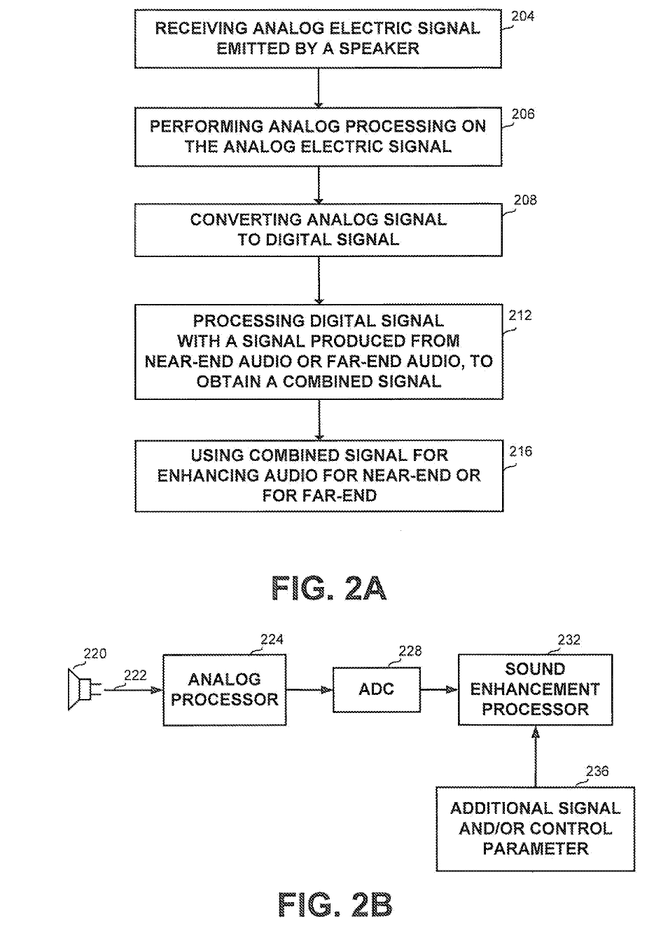

Referring now to FIG. 2A, showing a flowchart of the main steps in enhancing audio using a speaker as a microphone.

On step 204, the electric signal emitted by a speaker connected as a microphone is received. The signal is an analog signal, produced by the speaker which is used as a microphone, in reaction to the sound received by the speaker. The sound received by the speaker may consist of near end sound, far end sound output by the speaker, and echo generated from the near-end sound or the far-end sound.

On step 206, analog processing is performed on the analog signal, including gaining or any pre-processing such as analog filtering.

On step 208, the analog electric signal is converted into a digital signal by a digital-to-analog (DAC) converter.

On step 212, the digital signal is processed together with one or more other digital signals, which are products of processing the near-end audio or the far-end audio. The decision with which audio the digital signal is processed, and the type of processing being performed, depends on the specific application. It will be appreciated that if the digital signal is processed with a near-end audio product, the near-end audio is preferably received also by another microphone, such as microphone 108 of FIG. 1. The processing product is a combined signal.

After step 212, the combined signal may undergo further processing, either alone or with another signal produced from far-end audio or near-end audio, to produce a further combined signal.

On step 216, the combined signal, as may have been further processed, is used for enhancing the audio transmitted to the near-end speaker or to the far-end, i.e., it is transmitted to the near end or far end.

Referring now to FIG. 2B, showing a block diagram of the main components in a system for enhancing audio by using a speaker also as a microphone.

The system comprises a speaker 220, which is connected as a microphone, such that based on the sound received by the speaker-as-microphone 220, an analog signal 222 is output. Speaker 220 can be a single or one out of a multiplicity of speakers available in a device, and may be actively used by the user, such as an earpiece, or a free speaker such as a back speaker in a regular, i.e., non-handsfree talk. Speaker 220 is used for any audio enhancement purpose, including but not limited to echo cancellation, double talk detection, automatic listening enhancement, noise reduction, or the like. The analog signal is fed into analog processor 224, which enhances the analog signal by performing gaining and optionally additional operations, including analogue filtering such as DC removal. The enhanced signal is fed into analog-to-digital converter (ADC) 228, which outputs a corresponding digital signal. The digital signal is then fed to audio processor 232. Processor 232 preferably receives additional one or more signals and/or control parameters 236 from other sources, and using all input signals and/or control parameters performs processing which enhances the sound for the far-end or the near-end. Processor 232 emits the enhanced digital signal.

Referring now to FIG. 3, showing a block diagram of a system implementing a first application of the method of FIG. 2A. The first application is an echo cancellation system that uses the speaker as a transmitting microphone in full duplex in order to enhance the quality of sound transmitted to the far-end. The application provides for enhanced acoustic echo cancellation (AEC) or acoustic echo suppression (AES) when the only available microphone is the speaker when used also as a microphone, by providing perfect synchronization between the far-end signal and the echo.

Far end signal 304 is received by the unit comprising the speaker. The signal is received as a digital signal, and undergoes pre-processing by digital preprocessor 308. The processed signal is then converted to an analog signal by digital-to-analog converter (DAC) 312, and then undergoes analog processing by analog processor 316, including gain/attenuation enhancement. The processed signal is input into speaker 320. Speaker 320 is also connected as a microphone, and outputs an analog signal 322 reflecting the far-end signal, the near-end signal, and echo. Signal 322 undergoes analog processing by processor 324, which is similar to processor 224 of FIG. 2B. The resulting signal is converted into a digital signal by ADC 228, and then fed as signal 330 into AEC/AES processor 332. AEC/AES processor 332 receives also the far-end signal 334 as output by digital preprocessor 308. No additional microphone is required in this embodiment.

The availability to processor 332 of the far-end signal 334, as well as signal 330 enables improved signal activity detection (SAD), i.e., which side talks on each particular point in time. SAD and double-talk (DT) detection are important for proper operation of processor 332 and enhancing the output signal which is transmitted to the far-end. The use of speaker-as microphone and echo cancellation also provide for significant improvement in double-talk (DT) detection in comparison to other methods.

In some implementations processor 332 performs adaptive filtering which filters the echo of the far end is sound, and non-linear processing (NLP) which suppresses and adds attenuation to the near-end signal.

However, depending on the activity, i.e., which side speaks it every point in time, one or more of the filter adaptation and NLP should be eliminated. Thus, when the near-end is active, filter adaptation as well as NLP are not required and should be eliminated, in order to avoid discontinuities or other artifacts. If the near-end is silent, then the operation of processor 332 depends on the far-end activity. If the far-end is active, adaptation is performed on the signal received from the far-end, and on the background noise otherwise. The manner in which the NLP is activated is also affected by the activity of the far-end.

Therefore, the match between the far-end signal and the signal received by the speaker-as-microphone provides for enhanced operation of processor 332 and better sound quality is transmitted to the far-end.

Referring now to FIG. 4, showing a block diagram of a system implementing a second application of the method of FIG. 2A. The second application is also aimed at improving the quality of the sound transmitted to the far-end, in full-duplex environment.

While in the first application, as shown in FIG. 3, the only microphone available in the system is the speaker-as microphone, in this application as shown in FIG. 4 there is available an additional microphone, such as the dedicated microphone of a mobile phone. This application can be used, for example, in a mobile phone in which a speaker is also used as a microphone.

In the second application as shown in FIG. 4, the sound received from the speaker-as-microphone is used only for improving SAD and DT detection, while the echo cancellation and suppression is performed on the sound received from the additional microphone, as in conventional systems and methods.

Processor 408, DAC 412, analog processor 416, speaker 420, analog processor 424 and ADC 428 are similar and correspond to processor 308, DAC 312, analog processor 316, speaker 320, analog processor 324 and ADC 328, respectively.

Signal 430, received from ADC 428 is fed into ST Detection/SAD component 452, which outputs signal 434 indicating which side or sides are active at every point in time.

Additionally, analog sound signal 442 received from microphone 440 is fed into analog processor 444 which is similar to analog processor 416, and then to ADC 448. Signal 442 comprises the near-end sound, as well as background noise, and echo of the far-end sound as captured by the speaker connected as microphone. Digital Signal 450, which is output from ADC 448, is fed into AEC/AES processor 432, which is similar and corresponds to AEC/AES processor 332 of FIG. 3. However, signal 450 received by processor 432 does not include the far-end sound, but only the near-end sound, background noise and echo of far-end sound. Signal 436, on the other hand, does not include the echo but only the far-end sound. Signals 436 and 450, together with SAD/DT detection signal 434 provide for better adaptation or non-linear processing by AEC/AES processor 432, and thus higher sound quality to be transmitted to the far-end.

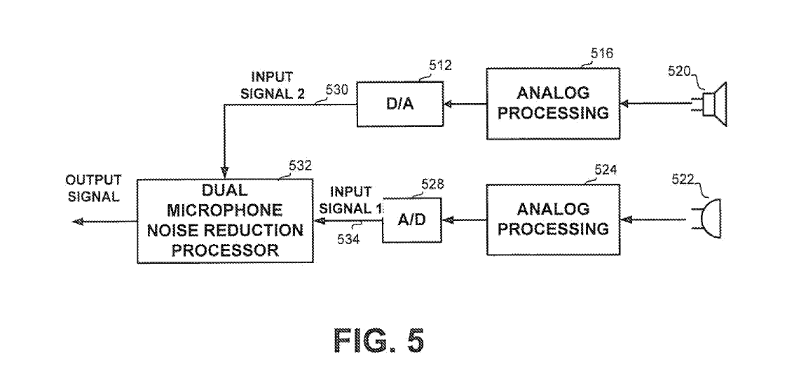

Referring now to FIG. 5, showing a block diagram of a system implementing a third application of the method of FIG. 2A. The system of FIG. 5 provides for a microphone array noise reduction of the sound transmitted to the far-end, wherein no additional microphone is required. In some embodiments of the system of FIG. 5, a single microphone can be used which yields the effect of dual-microphone noise reduction (DMNR) or even multi-microphone noise reduction, through the usage of one or more speakers as microphones.

Within the system of FIG. 5, speaker 520 is also used as a microphone. The analog signal received from speaker 520 is processed by analog processor 516, which is similar to analog processor 316 of FIG. 3, The processed analog signal is then converted to a digital signal by ADC 512.

Microphone 522 outputs an analog signal in accordance with the near-end sound. The signal undergoes analog processing by analog processor 524 and analog to digital conversion by ADC 528, similar to analog processor 516 and ADC 512 above.

Signal 530 which is the processed and converted signal received form the speaker as microphone, as well as signal 534 which is the processed and converted signal received from the regular microphone, are fed into a dual microphone noise reduction component 532. The output of processor 532 is then transmitted to the far-end, and provides enhanced noise-reduced sound.

The third application thus enables the usage and advantages of a dual microphone noise reduction processor, even in situations in which only one microphone is available, by using one or more speakers as microphones as well.

The third application can be used by any end-device having, any one or more speakers, such as an earpiece, a handset speaker or a handsfree speaker.

It will be appreciated that one or more additional speakers such as speaker 520 may be connected as microphones and output signals which undergo analog processing and analog to digital conversion. The signals can then be fed to a microphone array noise reduction processor.

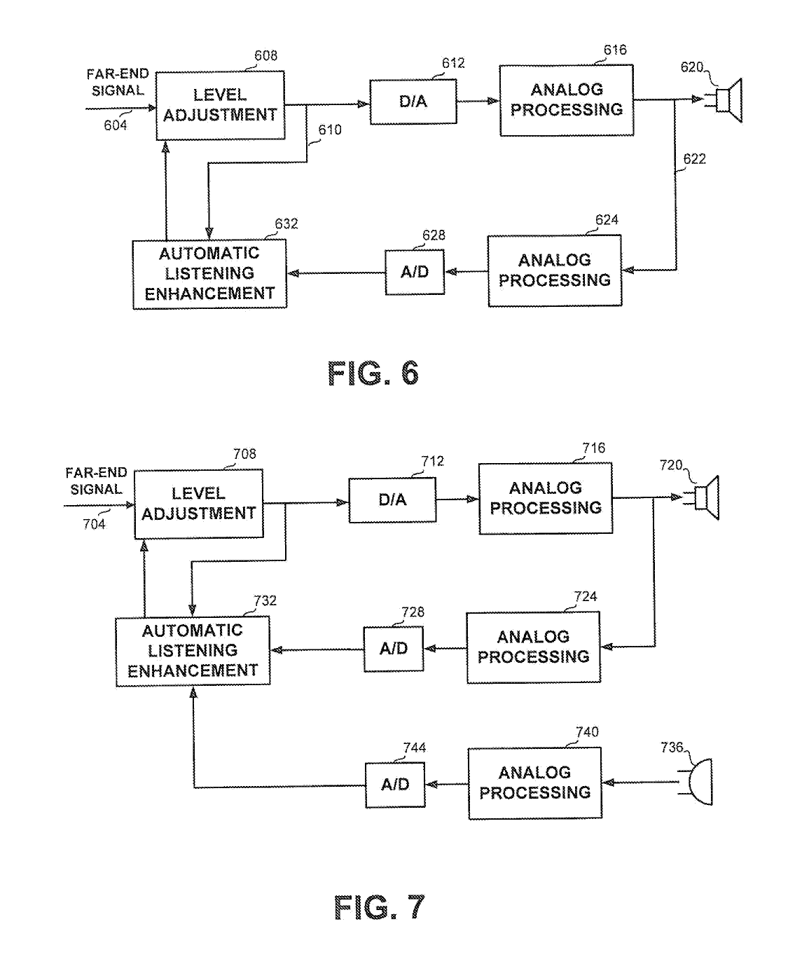

Referring now to FIG. 6, showing a block diagram of a system implementing a fourth application of the method of FIG. 2A. The system of FIG. 6 provides for near-end automatic listening enhancement, also referred to as active level control, i.e. adjusting the level at which the near-end receives the signal from the far-end, according to the background noise at the near-end environment. For example, for a person speaking on the phone in an airplane, the far-end sound will be amplified more than for a person in a quite environment.

In FIG. 6, the far-end signal is received and its level is adjusted by level adjustment processor 608. The adjusted signal undergoes digital to analog conversion by DAC 612, and analog processing by analog processor 616. The signal is then transferred to speaker 620. DAC 612 and analog processor 616 are similar to DAC 312, and analog processor 316 of FIG. 3 above.

Speaker 620 is any speaker in the end-terminal, such as a handset speaker or a handsfree speaker. Speaker 620 is connected as a microphone, and outputs an analog signal corresponding to the background noise. Signal 622 thus comprises the background noise as well as the far-end audio. Signal 622 undergoes analog processing by analog processor 624 and analog to digital conversion by ADC 628. Analog processor 624 and ADC 628 are similar to analog processor 324 and ADC 328 of FIG. 3 above. The digital signal, as well as signal 610 which is the output of level adjustment processor 608, are fed into automatic listening enhancement processor 632. Thus, processor 632 receives the far-end audio, as well as the background noise together with the far-end audio, and can therefore isolate the background noise and send a level adjustment signal to level adjustment processor 608 which adjusts the level of the far-end audio to overcome the background noise.

It will be appreciated that level adjustment of the far-end signal is merely an example, and other noise control operations can be performed as well.

The system shown in FIG. 6 thus provides for near-end level adjustment of the signal coming from the far-end in a single-microphone environment, in accordance with the background noise.

Referring now to FIG. 7, showing a block diagram of a system implementing a fifth application of the method of FIG. 2A. The system of FIG. 7 provides for dual-microphone near-end active level control. In the system of claim 7, any free speaker in the system, such as a handsfree speaker or a handset speaker is used as a second microphone.

The system of FIG. 7 comprises level adjustment processor 708, DAC 712, analog processors 716 and 726, speaker 720, ADC 728, and automatic listening enhancement processor 732, which are analogous to level adjustment processor 608, DAC 612, analog processors 616 and 626, speaker 620, ADC 628 and automatic listening enhancement processor 632, respectively. The system of FIG. 7 further comprises microphone 736, the output of which undergoes analog processing by analog processor 740 and analog to digital conversion by ADC 744. The signal output by ADC 744 is fed into automatic listening enhancement processor 732, in addition to the signal output by ADC 728 and the signal output by processor 708. Automatic listening enhancement processor 732 uses the diversity between the signal output by microphone 736 and speaker-as-microphone 720 to detect the background noise and analyze the required adjustment. The adjustment signal is then fed into level adjustment processor 708 to adjust the far-end signal in accordance with the background noise.

The disclosed method and the applications using the method use a speaker available in a system as a microphone, for various aspects of enhancing the audio quality, whether from the far-end or for the near-end.

It will be appreciated that multiple additional application can be designed using the method of FIG. 2A, and that the applications shown in FIGS. 3-7 are merely examples and do not limit the scope of the disclosure. It will also be appreciated that any of the systems of FIG. 3-FIG. 7 can be implemented in additional ways, while using the output of a speaker connected as a microphone.

It will be appreciated that the disclosed embodiment is exemplary only, and that other embodiments can be designed for performing the methods if the disclosure. In particular, each component can be implemented as a collection of multiple components. Alternatively, a single component can provide the functionality of multiple described components.

It will be appreciated by persons skilled in the art that the present disclosure is not limited to what has been particularly shown and described hereinabove. Rather the scope of the present disclosure is defined only by the claims which follow.

What is claimed is:

1. A system for enhancing audio quality in a communication device in which a near-end user is communicating with a far-end, comprising:
a speaker connected as a microphone;
an analog processor for processing a first analog signal output by the speaker and outputting an enhanced analog signal;
an analog to digital converter for converting the enhanced analog signal into a digital speaker signal; and
a sound enhancement processor for receiving the digital speaker signal and a second signal produced from near-end audio or from far-end audio, and for generating an enhanced digital signal.

2. The system of claim 1 wherein the sound enhancement processor is an acoustic echo cancellation or acoustic echo suppression processor, and wherein the first analog signal also comprises a signal produced from the far end audio, and wherein the second signal is produced from far end audio, and wherein the enhanced digital signal is transmitted to the far end.

3. The system of claim 1 wherein the sound enhancement processor is a double talk or signal activity detection processor, the system further comprising:
a microphone transmitting a second analog signal;
a second analog processor for processing the second analog signal and obtaining an enhanced second analog signal;
a second analog to digital converter for converting the enhanced second analog signal into a microphone digital signal; and
an acoustic echo cancellation or acoustic echo suppression processor for receiving the microphone digital signal, the enhanced digital signal output by the double talk or signal activity detection processor, and the second signal produced from far end audio, and for producing output signal,
wherein the first analog signal also comprises a signal produced from the far end audio, and wherein the output signal is transmitted to the far-end.

4. The system of claim 1 wherein the sound enhancement processor is a microphone array noise reduction processor, the system further comprising:
at least one microphone transmitting at least one second analog signals;
at least one second analog processor for processing the at least one second analog signal and obtaining at least one second enhanced analog signal; and
at least one second analog to digital converter for converting the at least one second enhanced analog signal into at least one microphone digital signal,
wherein the second signal is the at least one microphone digital signal produced from the near end audio, and wherein the enhanced digital signal is transmitted to the far end.

5. The system of claim 1 wherein the sound enhancement processor is an automatic listening enhancement processor, the system further comprising:
a level adjustment processor for adjusting the far end audio in accordance with a signal output by the a automatic listening enhancement processor and for outputting an adjusted digital signal;
a digital to analog convertor for converting the adjusted digital signal into an adjusted analog signal; and
a second analog processor for processing the adjusted analog signal and outputting an enhanced analog signal;
wherein the second signal is the adjusted digital signal, and wherein the first analog signal also comprises a signal produced from the far end audio, and wherein the enhanced analog signal is transmitted to the near end.

6. The system of claim 1 wherein the sound enhancement processor is an automatic listening enhancement processor, the system further comprising:
a microphone transmitting a microphone analog signal;
a second analog processor for processing the microphone analog signal, and outputting an enhanced microphone signal;
a second analog to digital converter for converting the enhanced microphone signal into a microphone digital signal; and
a level adjustment processor for adjusting the far end audio in accordance with a signal output by the automatic listening enhancement processor and for outputting an adjusted digital signal,
wherein the second signal is the adjusted digital signal and the microphone digital signal, and wherein the enhanced digital signal is transmitted to the near end.

7. A method for enhancing audio quality in a communication device in which a near-end user is communicating with a far-end, comprising:
receiving a first analog signal from a speaker connected as a microphone;
processing the first analog signal;
converting the first analog signal to a digital signal;
performing sound processing on the digital signal with a second signal produced from near-end audio or from far-end audio, to obtain an enhanced signal; and
transmitted the enhanced signal or a product thereof for enhancing audio transmitted to the near-end or to the far-end.

8. The method of claim 7 wherein the sound processing is acoustic echo cancellation or acoustic echo suppression, and wherein the first analog signal also comprises a signal produced from the far end audio, and wherein the second signal is produced from the far-end audio, and wherein the enhanced digital signal is transmitted to the far end.

9. The method of claim 7 further comprising:
receiving a second analog signal from a microphone;
processing the second analog signal to obtain a second enhanced analog signal;
converting the second enhanced analog signal into a microphone digital signal; and
performing acoustic echo cancellation or acoustic echo suppression on the microphone digital signal,
wherein the sound processing is double talk detection or signal activity detection, and wherein the acoustic echo cancellation or acoustic echo suppression is performed in accordance with the double talk detection or signal activity detection, and in accordance with the second signal produced from far-end audio,
and wherein the first analog signal also comprises a signal produced from the far end audio, and wherein the enhanced digital signal is transmitted to the far end.

10. The method of claim 7 further comprising:
receiving at least one second analog signal from at least one microphone;
processing the at least one second analog signal to obtain at least one second enhanced analog signal; and
converting the at least one second enhanced analog signal into at least one microphone digital signal,
wherein the sound processing is microphone array noise reduction, and wherein the enhanced digital signal is transmitted to the far end.

11. The method of claim 7 wherein the sound processing is automatic listening enhancement producing an automatic listening enhancement signal, the method further comprising:
adjusting the level of the far end signal in accordance with the automatic listening enhancement signal to obtain an adjusted digital signal;
converting the adjusted digital signal into an adjusted analog signal; and
processing the adjusted analog signal,
wherein the first analog signal also comprises a signal produced from the far end audio after adjustment, and wherein the enhanced digital signal is transmitted to the near end.

12. The method of claim 7 wherein the sound processing is automatic listening enhancement producing an automatic listening enhancement signal, the method further comprising:
adjusting the level of the far end signal in accordance with the automatic listening enhancement analysis signal to obtain an adjusted digital signal;
converting the adjusted digital signal into an adjusted analog signal;
processing the adjusted analog signal;
transferring the adjusted analog signal to the speaker;
receiving a second analog signal from a microphone;
processing the second analog signal to obtain a second enhanced analog signal; and
converting the second enhanced analog signal into a microphone digital signal,
wherein the second signal is the adjusted digital signal and the microphone digital signal, and wherein the enhanced digital signal is transmitted to the near end.
